(19) United States
(12) Patent Application Publication
(10) Pub. No.: US 2013/0208761 A1
(43) Pub. Date: Aug. 15, 2013

(54) Instrument with Non-contact Infrared Temperature Measurement and Current Clamp

(71) Applicant: General Tools and Instruments, (US)

(72) Inventor: Roger Mavrides, Canton, MA (US)

(73) Assignee: General Tools and Instruments, New York, NY (US)

(21) Appl. No.: 13/766,977

(22) Filed: Feb. 14, 2013

Related U.S. Application Data
(60) Provisional application No. 61/598,501, filed on Feb. 14, 2012.

(51) Int. Cl. G01J 5/02; G01R 19/00

(52) U.S. Cl. CPC G01J 5/0265; G01R 19/00
USPC 374/121

(57) ABSTRACT

A multi-meter performs multiple measurement functions and includes a housing with a longitudinal axis and a measurement display. The multi-meter further includes a clamp arm type current measuring instrument. The clamp arms are generally aligned with the longitudinal axis of the multi-meter housing. The multi-meter also includes a non-contact infrared temperature measurement device contained in a module attached to the stationary clamp arm of the current measuring instrument. The module is arranged so that the non-contact infrared temperature measurement instrument receives a cone of infrared energy along the longitudinal axis and the cone of infrared energy is not obstructed by the housing or clamp arms.

### CROSS-REFERENCE TO RELATED APPLICATIONS

This application claims the benefit under 35 U.S.C. §119(e) of U.S. Provisional Patent Application No. 61/598,501, filed Feb. 14, 2012, which is hereby incorporated by reference in its entirety.

### FIELD OF THE INVENTION

The invention relates to an instrument having multiple functions such as a multi-meter including a current clamp and a non-contact infrared temperature measurement instrument contained in a module attached to an arm of the current clamp so that the field of view of the infrared temperature measurement is not obstructed.

### BACKGROUND OF THE INVENTION

In relatively large electrical distribution systems, e.g., those in large plants, factories or stadiums, electricians are required to travel over significant distances to engage in repair and maintenance of the system. In addition they must carry their electrical measurement equipment over these same distances. This equipment can include devices to measure electrical voltage and current. If the distribution system is used to power equipment that uses a lot of electricity, e.g., stadium lights and/or motors spread out over a large area, it may also be necessary for the electricians to have devices for measuring heat, e.g., the temperature of a motor or transformer, as a means of diagnosing problems.

One way of relieving the burden is to equip the electricians with multi-meter devices, i.e., single devices that are capable of measuring different electrical or heat parameters. An example of such a device is shown in U.S. Pat. No. 7,163,336 of Blakeley. The Blakeley multi-meter includes current sensing clamps, a non-contact heat sensor with a laser pointer, and voltage sensing jacks. It also includes a large display for showing the results of measurements made by the device. Push buttons and a rotary switch on the device are used to select the measurement mode and range, as well as the information displayed.

One problem with the multi-meter of Blakeley shown in FIG. 1 of that patent is that the cone of detection of infrared (IR) energy used to determine heat is partially blocked by the stationary clamp of the current measurement device. This creates potential errors in the IR reading, and hence errors in the detected heat. FIGS. 7 and 8 of the Blakeley patent show the IR sensor directed out of the side of the device at 90° to its axis so there can be unobstructed receipt of IR energy. However, it is difficult to hold and target an object with the device at such an angle, and it puts strain on the user's wrist. When the IRT sensor is oriented at the top end of the meter it is easy to use and reduces strain on the user's wrist. It also allows the user to measure the temperature of conductors and equipment directly at the top/front of the meter, even with the clamps engaged about a conductor while making current measurements.

Another problem with the Blakeley IR detector is that the meter has to be set to display its results. This requires the electrician to engage in additional manipulations to achieve a reading. Further, the Blakeley IR detector is fixed in relation to the multi-meter device, so aiming it and placing it in a measurement position is limited by the housing of the multi-meter.

While the Blakeley device has jacks for making contact via leads with electrical conductors for the purpose of measuring voltage, it is frequently beneficial to measure voltage using a non-contact device. Such a device senses the electromagnetic field of a conductor carrying AC current when placed in proximity thereto. U.S. Pat. No. 7,030,599 of Douglas discloses an example of such a non-contact voltage detector. These devices eliminate or at least reduce the risk of harmful electrical shock associated with contact type devices. However, it is not common to incorporate non-contact voltage measuring devices into multi-meter devices. Also, the Douglas device merely detects the presence of AC voltage, but does not measure it.

Thus, it would be advantageous to have a multi-meter with an IR sensor that is easy to aim and which receives the entire cone of IR energy from the source. It would also be of benefit to include a non-contact voltage measuring device in the meter. Further, it would be good to be able to easily distinguish the readout of IR energy from that of other electrical measurements without having to manipulate controls.

### SUMMARY OF THE INVENTION

The present invention is directed to an improved electrical multi-meter equipped with an infrared temperature sensor that is easy to aim and which receives the full cone of energy from a temperature source.

In an illustrative embodiment the multi-meter has multiple measurement functions and is enclosed in a longitudinal housing having a longitudinal axis. The housing has a measurement display on its outer surface.

Within the multi-meter there is a current measuring instrument including a stationary clamp arm and a pivotable clamp arm generally aligned with the longitudinal axis of the housing. The clamp arms can be placed around a wire conducting a current that is to be measured. The electromagnetic field produced by said current to be measured is induced in the clamp arms, amplified, measured and the measurement results displayed on the measurement display of the housing.

The multi-meter also includes a non-contact infrared (IR) temperature measurement instrument contained in a module detachably fastened to the stationary clamp arm of the current measuring instrument. The IR temperature module is arranged so that it generally receives a cone of infrared energy along the longitudinal axis of the housing and the cone of infrared energy is not obstructed by the housing or clamp arms. The received infrared energy is measured, converted to a temperature and displayed on the measurement display of the housing and a separate IR display on the module. A laser pointer that produces a fine light beam aligned with the non-contact infrared temperature measurement module is provided so as to aid in sighting a target whose temperature is being measured.

In addition to displays for showing the results of electrical measurements, the multi-meter may also have an annunciator which produces at least one audible tone when the measurement indicates an alarm condition. The annunciator may also produce an audible tone when the multi-meter checks continuity and finds that there is continuity.

The multi-meter housing is made of insulative material, preferably plastics, and it is portable and battery operated. The detachable IR temperature measurement module may have its own separate battery so that is can operate independent of the meter.

The exterior surface of the housing further includes at least two test jacks on the housing and the interior of the housing has a digital measurement device for measuring voltage, capacitance, frequency, resistance and/or continuity of circuits placed across the test jacks, depending upon the measurement mode of the meter. In order to set the mode, the meter has a multiple function switch which determines the measurement mode including current measurement with the clamp arms, infrared temperature measurement, voltage, capacitance, frequency, resistance and/or continuity.

In one embodiment the multi-meter includes a plug from receiving a thermocouple, and a device in the housing for converting an input signal from the thermocouple into a temperature signal that can be displayed. It may include a light arranged to shine its beam along the longitudinal axis and a light switch to control whether the light is on or off.

A still further embodiment of the multi-meter includes a non-contact voltage detector capable of detecting the presence of an alternating current voltage at a particular point without actually contacting the point. The voltage detector is located at the front end of the movable clamp arm and has a size such that it does not obstruct the received infrared energy. Further, the forward end of the non-contact voltage detector does not extend forward of the non-contact infrared temperature measurement module in the longitudinal direction.

### BRIEF DESCRIPTION OF THE DRAWINGS

The foregoing and other features of the present invention will be more readily apparent from the following detailed description and drawings of illustrative embodiments of the invention in which:

FIG. 1 is a front view of the multi-meter according to the present invention;

FIG. 2 is a rear view of the infrared temperature (IRT) measurement module in an embodiment of the invention wherein the module is detachable from the instrument;

FIG. 3 is a side view of the module of FIG. 2;

FIG. 4 is an end view of the IRT module in another embodiment of the invention;

FIG. 5 is a schematic circuit diagram of the IRT module; and

FIG. 6 is a schematic block diagram for the multi-meter according to the present invention.

### DETAILED DESCRIPTION OF THE INVENTION

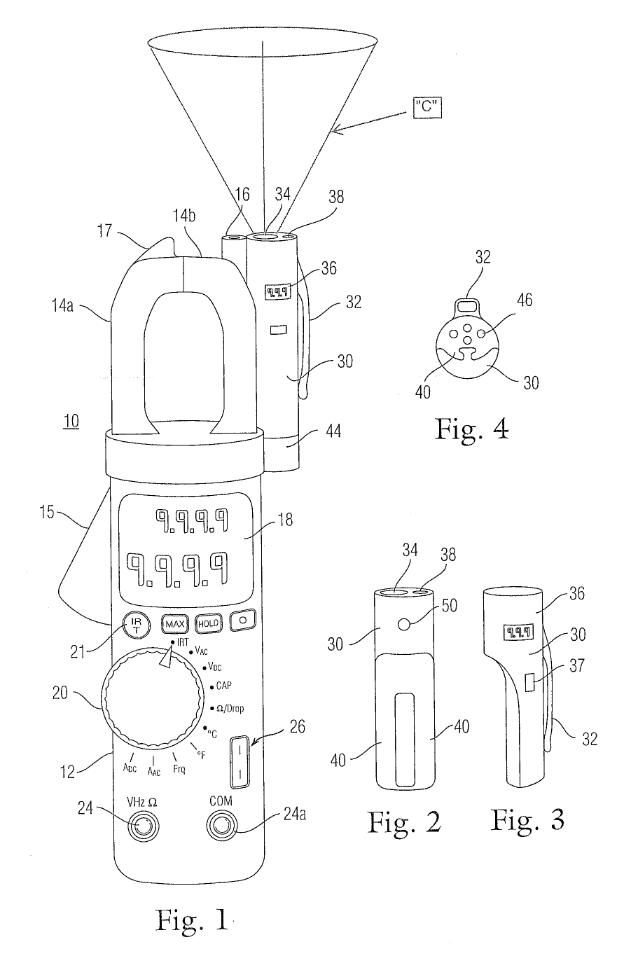

The instrument 10 of the invention has multi-functions. A preferred embodiment of the invention is shown in FIG. 1 in the form of a conventional multimeter that has other functions. The instrument 10 has a case or housing 12 of any suitable material such as plastic. The housing contains all of the necessary electronic circuitry, including a microprocessor and a power supply such as a disposable or rechargeable battery, to perform the various functions described below, See FIG. 6. Components within the housing 12 include those of a standard digital type multimeter for measuring voltage, current, capacitance, frequency, resistance and continuity. All of these functions and the circuitry therefore are conventional and well known in the art.

The instrument 10 has a digital display 18, such as an LCD display, that is connected to the instrument circuitry to display the various parameters that are measured. There is a control knob 20 for switching the operation mode of the instrument to perform its various functions as desired. This is described below. A pair of test lead jacks 24 and 24a are at the bottom of the instrument housing to accept the plugs of the leads (not shown) which have conductive ends to contact the points of a device or circuit to measure its electrical parameters, such as voltage. Jack 24a is illustratively shown as electrical common and 24 as the active terminal. There also is a socket 26 to accept the plug or leads of a thermocouple device for measuring temperature. The thermocouple devices can be located within the housing 12 or as part of an assembly with the test leads. The internal terminals of the jacks 24 and 26 are connected to the appropriate circuitry in the housing 12.

At the top end of the housing 12 there are arms 14a and 14b of a current clamp for measuring the current flowing in a conductor. Arm 14b is fixed to the housing 12 while arm 14a is releasably pivotally mounted to the top-end of the housing 12. A spring-loaded trigger type latch 15 actuates movement and positioning of the arm 14a. The latch permits the arm 14a to be pivoted relative to the stationery arm 14b so that it can be opened and closed so the two arms to be placed around a wire to determine if an electrical current is flowing in it and to measure the amount of current. Lead wires extend from one or both of the arms 14a and 14b to the circuitry in the instrument which determines and displays the measured current on the display 18.

At the top end of the stationery clamp arm 14b there is a light source 16 such as an LED. Wires or leads of a printed circuit extend within the arm 14b to the switch and power supply in the housing 12. The light source 16 is switched on and off as desired by the instrument user. This light allows the electrician or other user to see better in dark spaces.

At the top end of the movable arm 14a there is the sensing element, or probe, of a non-contacting voltage detector (NCV) 17. Such a device, detects the presence of an alternating current voltage at a particular point without actually contacting the point. A typical device of this type is shown in U.S. Pat. No. 7,030,599. The probe is connected to a circuit within the housing 12 that produces a signal when the voltage has been detected. The signal can be one or both of visual, such as a flashing LED, and/or audible.

The instrument includes an infrared temperature (“IRT”) module 30 mounted to the outside of the stationery clamp arm 14b. The module 30 is a case of a suitable material, such as plastic, and internally includes an IRT detector 34 and the necessary circuitry for measuring the temperature of a target. There also preferably is a laser 38 that produces a beam of light to sight the target whose temperature is being measured by the IRT detector 34. As seen in FIG. 1 the front end of the IRT detector 34 extends beyond the top of the clamp arms 14 and is not obstructed by any other part of the instrument so that it can receive the entire cone C of IR energy from the target. This is different from the arrangement shown in U.S. Pat. No. 7,163,336 wherein the IRT detector is at the end of the case, or housing, offset from the bottom of one of the clamp arms, thereby causing a portion of the cone of the IR energy emitted from the target to be blocked from reaching the IR detector.

In one embodiment of the invention, the IRT module 30 is fixed to the housing 12 and there would be leads from it extending to the instrument circuitry internal to the housing 12. In this embodiment, the temperature measured by the IRT module 30 and its internal circuitry is displayed on the instrument display 18.

In a preferred embodiment of the invention, the IRT module 30 is detachable from the instrument housing 12 and can function either in cooperation with or independently of the instrument housing 12. In this embodiment, the module 30 internally has the necessary circuitry and power supply, such as a battery, to accomplish this. As shown in FIG. 3, there is a switch 37 for actuating and turning off the IRT detector and laser when the module 30 is detached from the housing 12. This switch, or another switch (not shown), can be used to separately actuate the IRT measurement. The module 30 also has its own digital display 36, which can be an LCD display, for displaying the temperature that is measured. Typically this would only display temperature readings so that the user can distinguish the temperature reading from other readings that appear on display 18 without having to manipulate controls. There also can be a pocket clip 32 to enable the user to retain the module in a shirt pocket.

As shown in FIGS. 2 and 3 the module 30 has a pair of runners 40 defining a space there between which enables the module to be slid onto a track (not shown) on the clamp arm 14b. As before, the front end of the IRT detector 34 extends beyond the top of the clamp arm 14b so that there is no obstruction of the IR energy cone received by it.

In this embodiment in which the module 30 is detachable from the instrument, the module can be used to measure temperature either while mounted to the clamp arm 14b or detached from it. In the first case, the value of the IRT energy measured by the module IR detector 34 as processed by the module internal circuit is displayed on its own display 36 and signals of the temperature are provided back to the instrument housing 12 so that the measured temperature can also be shown on the instrument housing display 18. One way of accomplishing this is shown in FIG. 2 wherein the transmitting part of an electro-optical coupler 50 is provided on the module 30. This would interact with the receiving part of the coupler (not shown) on the clamp arm 14b which would convey the signals to the appropriate circuitry for the instrument housing display 18. Another way of coupling the signals from the module 30 to the instrument housing 12 is shown in FIG. 4 wherein pins 46 whose internal terminals are connected to the module internal temperature measuring circuitry are mounted on the bottom of the module 30. The pins 46 are inserted into a compatible jack 44 located at the top end of the housing 12. Therefore, when the module 30 runners 40 are slid on the track (not shown) of the clamp arm 14b, the module pins 46 would electrically make contact with the sockets of the jack 44. Further, if desired, there can be a wireless transmitter in the module 30 and a compatible receiver in the instrument housing 12 so that the temperature measured by the module 30 can be presented on the instrument display 18 in addition to the module display 36.

In embodiments of the invention where the module 30 is used to measure temperature while mounted to the housing 12, a control button 21 actuates this function. This will also send signals to the module 30, by way of either the plugs 44, 46 or the electro-optical coupler 50.

The instrument of the invention permits the IRT module 30 to be used totally independent of the rest of the instrument. That is, the module 30 can be detached from the clamp arm 14b and the user is free to measure temperatures of any target totally independent of the instrument 10. The relatively small size of the module 30 permits the user to manipulate the module in places and to measure temperatures of targets that could not be accessed if the module 30 was fixed to the clamp arm 14b. Returning to the instrument housing 12, there are illustratively four buttons 21 below the digital readout 18 that control the operation of the readout in the following manner, going from left to right:

IRT—causes an IRT measurement to be made by the module 30 with detector 32 and turns on the laser pointer 38 when the IRT module 30 is attached to the instrument as shown in FIG. 1. When the IRT button is depressed, signals are sent to the module 30 to activate its temperature measuring circuitry. When the button is released, the IRT measurement operation of module 30 is turned off but the measured temperature reading remains on the housing display 18 for a period of time, such as 15 seconds. The measure temperature reading is also displayed on module display 36. When the module 30 is detached from the housing 12 and a temperature is measured by the module sensor 32, it is displayed only on the module display 36 unless wireless communication is provided between the module 30 and the housing 12. In such a case it is displayed on both.

MAX/MIN—used for voltage and current maximum and minimum readings.

HOLD—used to store whatever reading is on the display.

TORCH/FLASH LIGHT; used to turn on the light source 16, press to turn on, press to turn off.

The control knob 20 controls the function of the instrument in the following manner, going clockwise from the top:

IRT Sets the circuitry for infrared temperature (IRT) measurement via IRT module 30 and is used in conjunction with the IRT button 21.

V_{AC} Sets instrument for measuring alternating voltage using standard test leads extending from the jacks 24 and 24a.

V_{DC} Sets the instrument for measuring direct voltage using the input jacks 24 and standard test leads.

CAP Sets the instrument to measure capacitance using the input jacks 24 and standard test leads

Ω/DROP—Resistance/Continuity/Diode Check—Sets the instruments for measuring resistance, checking continuity and checking for diode failure, using the input jacks 24 and standard test leads.

° F. Measures temperature using a thermocouple in degrees Fahrenheit using thermocouple jack 26 and standard test leads.

° C. measures temperature using a thermocouple in degrees Celsius, using thermocouple jack item 26 and standard test leads.

FREQ measures the frequency of alternating AC voltage or current using the clamp jaw 14 or the input jacks 24 and 24a.

A_{AC} Sets the current measured by the clamp 14 for alternating current, used only with the clamp jaws 14.

A_{DC} Sets the current measured by the clamp 14 for direct current, used only with the clamp jaws 14. This clamp meter can also measure DC current from the clamp jaw using a Hall Effect type of sensor contained in the housing. Hall Effect sensor technology is an industry recognized method for measuring DC current using clamp meters.

The instrument display 18 is a dual readout display that shows combinations of readings simultaneously. When measuring AC voltage or current, the bottom portion of the readout will display the voltage and the top will display frequency. When measuring frequency, the bottom display portion will display frequency and the top will display voltage. All of the settings have associated symbols (annunciators or lights) on the display 18 including a dynamic bar graph which will change with the changing values.

In addition the instrument has a beeper or buzzer that makes an audible tone used for alarm conditions and when checking continuity.

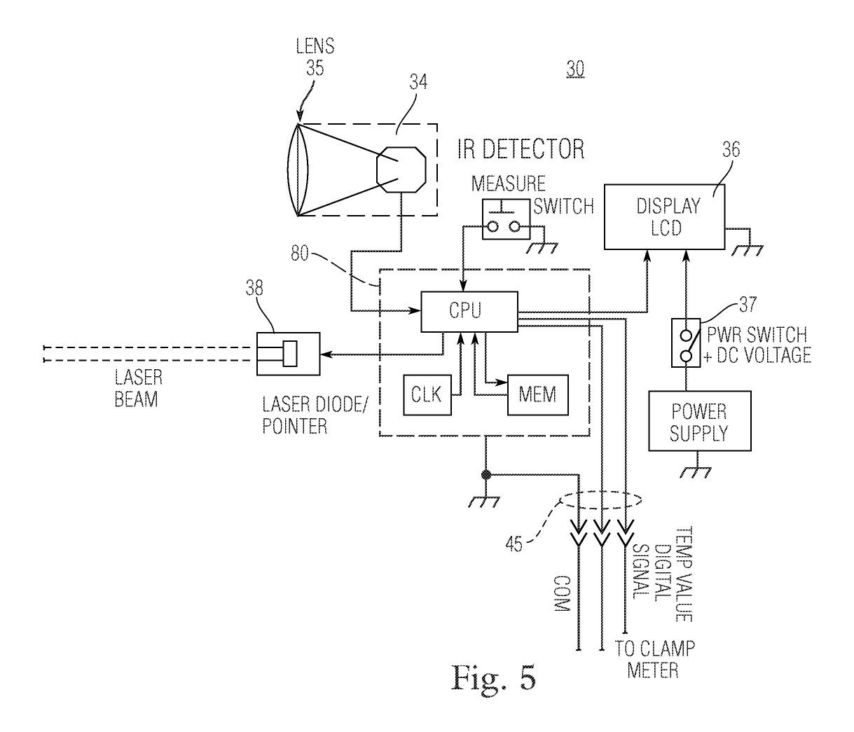

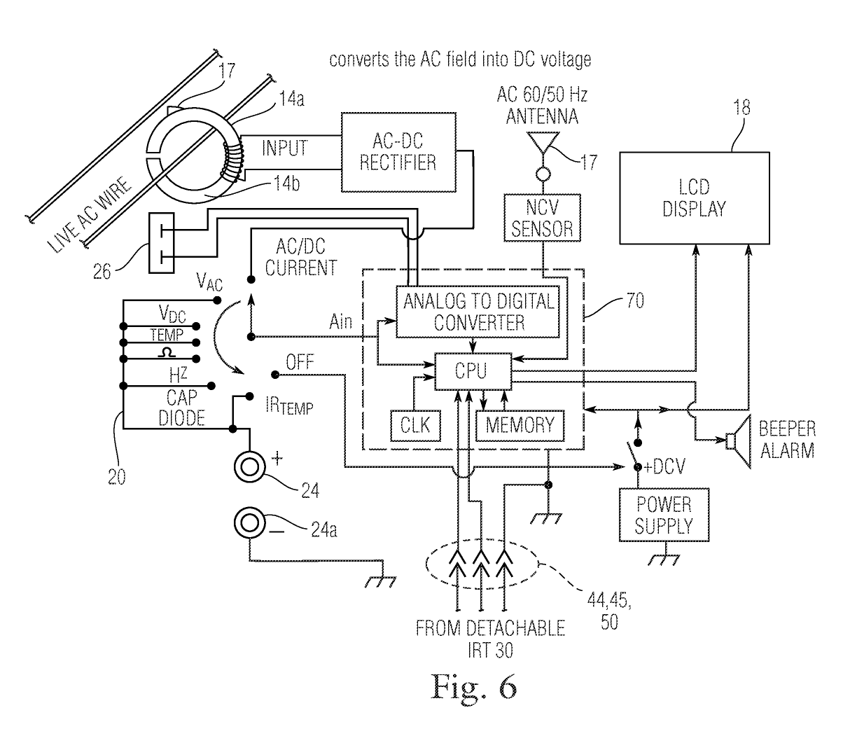

FIG. 5 is a schematic diagram of the IRT module 30 in which the various elements are numbered corresponding to the description given above. The IRT sensor 34 is shown as having a lens 35 for receiving the cone C of IR energy from a target. The IRT module 30 has an electronic integrated circuit 80 that includes an analog to digital converter and central processing unit (CPU), such as a microprocessor. The microprocessor produces digital signals in response to the analog signal produced by the IRT sensor 34. When the module 30 is detached from the instrument housing, the signals drive the module display 36. When the module is attached to the instrument housing 12, the digital temperature data produced by the circuit 80 is transferred through the connectors 45, 46 to a CPU in the instrument housing in serial digital format to display the measure temperature on the housing 12 display 18.

FIG. 6 is a schematic block diagram of the instrument in which the various elements are numbered corresponding to the description given above. Within the housing 12 is an electronics module 70. This includes an analog-to-digital converter to which is connected the thermocouple 26 for converting its measured analog signal into digital form to relay to a central processing unit, such as a microprocessor, within the module 70. The analog-to-digital converter and the microprocessor perform all of the measurement functions selected by the switch 20. The microprocessor produces digital output signals applied to the LCD display 18 to display all measured quantities such as those produced by the multimeter circuits, the IRT 34 of the module 30 and the current measured by the clamp 14.

While the invention has been particularly shown and described with reference to preferred embodiments thereof, it will be understood by those skilled in the art that various changes in form and details may be made therein without departing from the spirit and scope of the invention.

I claim:

1. A multi-meter having multiple measurement functions comprising:
a longitudinal housing having a longitudinal axis, said housing having a measurement display;
a current measuring device including a stationary clamp arm and a pivotable clamp arm generally aligned with the longitudinal axis, said clamp arms can be placed around a wire conducting a current to be measured, each clamp arm having at least one conductive wire therein in which a measurement current is induced based on the electromagnetic field produced by said current to be measured, the induced current being amplified and measured, and the measurement results being displayed on the measurement display of the housing; and
a non-contact infrared temperature measurement device located in the housing and aligned with the clamp arms, said non-contact infrared temperature measurement device being arranged so that it generally receives a cone of infrared energy along the longitudinal axis and the cone of infrared energy is not obstructed by the housing or clamp arms, the received infrared energy being measured, converted to a temperature and displayed on the measurement display of the housing.

2. The multi-meter as claimed in clam 1 wherein the non-contact infrared temperature measurement device is contained in a module attached to the stationary clamp arm of the current measuring instrument.

3. The multi-meter as claimed in clam 1 wherein the housing is made of insulative material, preferably plastics.

4. The multi-meter as claimed in claim 2 further including a display on the module which displays the temperature, wherein the module is detachable from the clamp arm and wherein the module communicates the temperature to the housing for display on the measurement display of the housing.

5. The multi-meter as claimed in claim 1 further including at least two test jacks on the housing and a digital measurement device within the housing for measuring at least one of voltage, capacitance, frequency, resistance and continuity of circuits placed across the test jacks depending upon a measurement mode which it is in.

6. The multi-meter as claimed in claim 5 further including a multiple function switch which determines the measurement mode it is in including current measurement with the clamp arms, infrared temperature measurement, voltage, capacitance, frequency, resistance and/or continuity.

7. The multi-meter as claimed in claim 1 further including a battery in the housing for powering the multi-meter.

8. The multi-meter as claimed in claim 2 further including a battery in the module for powering the non-contact infrared temperature measurement instrument.

9. The multi-meter as claimed in claim 1 further including a plug from receiving a thermocouple, and a device in the housing for converting an input signal from the thermocouple into a temperature signal that can be displayed.

10. The multi-meter as claimed in claim 1 further including a light arranged to shine a beam of light along the longitudinal axis and a light switch to control whether the light is on or off.

11. The multi-meter as claimed in claim 10 wherein the light is arranged in the module.

12. The multi-meter as claimed in clam 2 wherein the front end of the non-contact infrared temperature measurement module extends beyond the front end of the clamp arms.

13. The multi-meter as claimed in claim 1 further including a non-contacting voltage detector capable of detecting the presence of an alternating current voltage at a particular point without actually contacting the point, said voltage detector being located at the front end of the movable clamp arm and having a size such that it does not obstruct the received infrared energy.

14. The multi-meter as claimed in claim 12 wherein the non-contact infrared temperature measurement device is contained in a module attached to the stationary clamp arm of the current measuring device, the forward end of the non-contacting voltage detector does not extend forward of the non-contact infrared temperature measurement module in the longitudinal direction.

15. The multi-meter as claimed in claim 1 further including a laser pointer that produces a fine beam aligned with the non-contact infrared temperature measurement device so as to aid in sighting a target whose temperature is being measured.

16. The multi-meter as claimed in claim 1 wherein the measurement display is capable of showing combinations of measurements simultaneously.

17. The multi-meter as claimed in claim 1 further including an annunciator which produces on the measurement display a dynamic bar graph which changes with the changing values.

18. The multi-meter as claimed in claim 1 further including at least one device for generating an audible tone when the measurement indicates an alarm condition.

19. The multi-meter as claimed in claim 1 further including at least one device for generating an audible tone when the multi-meter checks continuity and finds that there is continuity.
